(19) United States
(12) Patent Application Publication
(10) Pub. No.: US 2009/0205703 A1
(43) Pub. Date: Aug. 20, 2009

(54) APPARATUS AND METHOD OF MOUNTING AND SUPPORTING A SOLAR PANEL

(75) Inventors: Salvador P. Umotoy, Antioch, CA (US); Jeffrey S. Sullivan, Castro Valley, CA (US); Mike Brennan, Austin, TX (US); Charles Gay, Westlake Village, CA (US); Theodossios V. Costuros, Manchaca, CA (US); Gary D. Williams, Round Rock, TX (US); Oscar Gomez, South San Francisco, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/368,887

(22) Filed: Feb. 10, 2009

Related U.S. Application Data
(60) Provisional application No. 61/028,795, filed on Feb. 14, 2008.
(60) Provisional application No. 61/036,691, filed on Mar. 14, 2008.

(51) Int. Cl. H01L 31/048; F24J 2/52; H01L 31/18; B23P 15/26

(52) U.S. Cl. 136/251; 126/704; 438/66; 29/890.033

(57) ABSTRACT

The present invention generally relates to a simple and cost effective device and method for mounting and supporting solar panels. A solar panel according to the present invention is supported from the backside via a plurality of elongated support members. The elongated support members may have open V-shaped or W-shaped arrangements and may be adhered to the solar panels through strong, flexible glue or double-sided tape that withstands significant environmental loads, such as wind uploading, yet remain flexible enough to minimize stress concentrations in the solar panels. The support members may be attached to a solar panel by a support member attachment module incorporated into an automated solar panel production line. A plurality of solar panels may be field mounted to a solar panel support structure having one or more piles or the like with at least a lower and upper transverse support rails spanning the plurality of solar panels.

### CROSS-REFERENCE TO RELATED APPLICATIONS

This application claims benefit of U.S. provisional patent application Ser. No. 61/028,795, filed Feb. 14, 2008 and U.S. provisional patent application Ser. No. 61/036,691, filed Mar. 14, 2008, each of which is herein incorporated by reference.

This application is related to U.S. application Ser. No. 12/202,199, filed Aug. 29, 2008 and U.S. application Ser. No. 12/201,840, filed Aug. 29, 2008.

### BACKGROUND OF THE INVENTION

1. Field of the Invention

Embodiments of the present invention generally relate to a device and method for mounting and supporting solar panels.

2. Description of the Related Art

Due to environmental concerns and the rise in the cost of traditional energy sources, the demand for use of renewable energy sources is steadily increasing. In particular, significant resources are being invested in developing low cost panels for the production of electricity from solar energy. However, many challenges remain in achieving this goal, such as efficient, low cost mounting of solar panels both in filed and rooftop environments.

Typically, solar panels are manufactured in a planar, rectangular configuration. A frame is then attached around the perimeter of the panel to facilitate mounting. Brackets are then attached to the frame about the perimeter of the panel via screws or some other mounting hardware. The brackets are then typically attached to mounting rails, which are attached to a structure that is to support the solar panel. This configuration and mounting approach results in a bulky solar panel configuration while adding significant cost to the production of the panel as well as the ultimate field installation.

Another approach is to mount a solar panel absent a frame. A typical embodiment is illustrated in FIGS. 1A and 1B. FIG. 1A is a top view of a prior art solar panel mounting configuration 100. According to this configuration, solar panel 110 is mounted via clamping members 120, such as C-clamps, about the perimeter of the panel 110. FIG. 1B is a partial, schematic, cross-sectional view of the mounting configuration 100 shown in FIG. 1A about line B-B. However, this approach is wrought with problems.

For example, this approach requires that the clamping members 120 be stiff and strong enough to support the panels 110 under significant loading from typical adverse environmental conditions, such as wind, ice, and snow. To accomplish this, the clamping members 120 are typically comprised of aluminum extrusions, designed to allow very little deflection. As a result of this design approach, high stress concentrations develop at the edges of the glass solar panels 110 under load. Thus, breakage of the solar panel 110 becomes a problem having significant repair/replacement expenses associated therewith.

Additionally, solar panels, by their very nature, are exposed to high temperature loading via exposure to solar radiation. At these high temperatures, the lamination material contained within the panels can liquefy. As a result, panels that are solely mounted by clamping at the perimeter may slip and shift out of position, which often results in improper orientation or breakage of the solar panel.

Accordingly, a need exists for a simple and cost effective device and method for mounting and supporting solar panels in a variety of environments.

### SUMMARY OF THE INVENTION

In one embodiment of the present invention, a solar panel assembly comprising a solar panel having a light receiving surface and a non-light receiving surface, a substantially V-shaped support member having a corrosion resistant coating, and a moisture resistant adhesive bonding member attaching the substantially V-shaped support member to the non-light receiving surface of the solar panel, wherein the substantially V-shaped member substantially spans a length of the solar panel.

In another embodiment of the present invention, a solar panel support attachment module comprises a system controller configured to send and receive commands, a solar panel cleaning region configured receive commands from the system controller and clean a non-light receiving surface of the solar panel, a solar panel drying module configured to receive commands from the system controller and dry the non-light receiving surface of the solar panel, a support member placement module configured to receive commands from the system controller and position a support member on the non-light receiving surface of the solar panel, a support member attachment module configured to receive commands from the system controller and attach the support member to the non-light receiving surface of the solar panel, and an automation system configured to receive commands from the system controller and move the solar panel through the solar panel support attachment module.

In another embodiment of the present invention, a method for attaching a support member to a solar panel comprises receiving the solar panel onto an automation device, positioning the solar panel within a cleaning module via the automation device, cleaning a non-light receiving surface of the solar panel, transferring the solar panel into a drying module via the automation device, drying the non-light receiving surface of the solar panel, transferring the solar panel into a support member placement module via the automation device, positioning a support member onto the non-light receiving surface of the solar panel, transferring the solar panel into a support member attachment module via the automation device, and attaching the support member to the non-light receiving surface of the solar panel.

In another embodiment of the present invention, a solar panel support assembly comprises a lower support structure, a lower transverse support rail attached to the lower support structure, an upper transverse support rail attached to the lower support structure, and an adhesive member affixed to the lower transverse support rail and the upper transverse support rail and configured to adhere to a non-light receiving surface of the solar panel. In one embodiment, the lower transverse support rail has a plurality of slots disposed therein each configured to receive a solar panel support member affixed to the solar panel. In one embodiment, the upper transverse support rail has a plurality of slots disposed therein each configured to receive the solar panel support member affixed to the solar panel.

In yet another embodiment of the present invention, a method for mounting a solar panel comprises affixing an adhesive member to an upper mounting surface of a lower transverse rail and an upper mounting surface of an upper transverse rail of a grounded lower support member, positioning the solar panel onto the adhesive member of the lower transverse rail and the upper transverse rail, and attaching the solar panel to the upper mounting surface of the lower transverse rail and the upper mounting surface of the upper transverse rail.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is top view of a prior art solar panel mounting configuration.

FIG. 1B is a partial, schematic, cross-sectional view of the mounting configuration shown in FIG. 1A.

FIG. 2A illustrates a cross-sectional view according to one embodiment of an elongated member for mounting a solar panel.

FIG. 2B illustrates an isometric view of the elongated member of FIG. 2A.

FIG. 3A illustrates a cross-sectional view according to another embodiment of an elongated member for mounting a solar panel.

FIG. 3B illustrates an isometric view of the elongated member of FIG. 3A.

FIG. 4 is a partial schematic cross-sectional view of one embodiment of a solar panel mounting configuration of the present invention.

FIG. 5 is a partial schematic cross-sectional view of the embodiment of the solar panel mounting configuration in FIG. 4 under exaggerated loading conditions.

FIG. 6 is an isometric view of one embodiment of an end bracket according to the present invention.

FIG. 7 is a partial cross-section view of one illustrative embodiment of a solar panel mounting configuration in accordance with the present invention.

FIG. 8 is an isometric view of a solar panel having elongated support members bonded thereto according to one embodiment of the present invention.

FIG. 9 is a plan view of a support member attachment module according to one embodiment of the present invention.

FIG. 10 is a schematic plan view of a solar panel field mounting configuration according to one embodiment of the present invention.

FIG. 11 is a schematic cross-sectional view of the mounting configuration as viewed along section A-A of FIG. 10.

FIG. 12A is a schematic enlarged view of the region of FIG. 11 labeled “Detail A.”

FIG. 12B is a schematic isometric view of the region depicted in FIG. 12A with the solar panel removed for clarity.

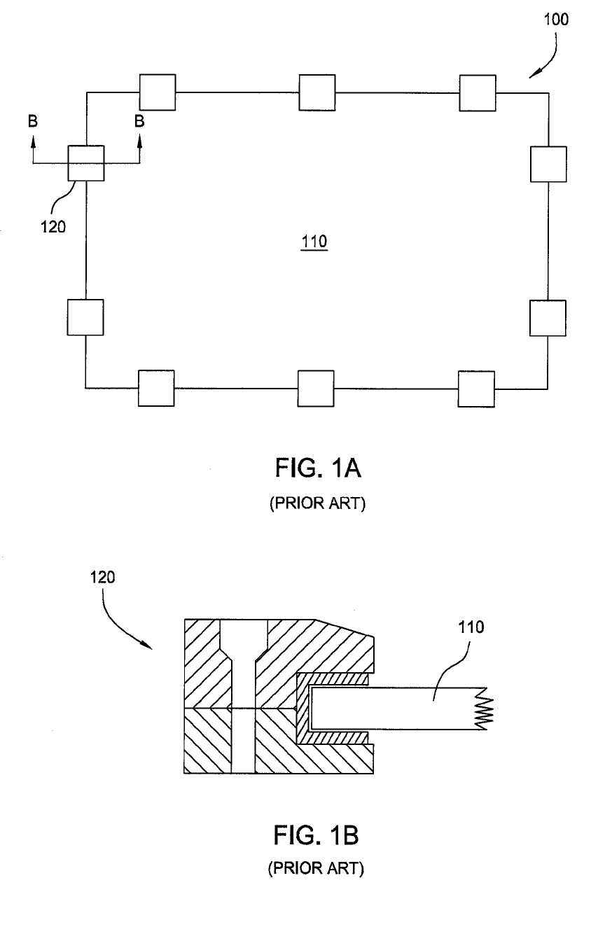

### DETAILED DESCRIPTION

The present invention generally relates to a simple and cost effective device and method for mounting and supporting solar panels. A solar panel according to the present invention is supported from the backside via a plurality of elongated support members. The elongated support members may have open V-shaped or W-shaped arrangements strong enough to support a solar panel under the required loading but flexible enough to minimize the maximum stress experienced by the solar cell during normal operation and exposure to the environment. The support members may be adhered to the solar panels through strong, flexible glue or double-sided tape that withstands significant environmental loads, such as wind uploading, yet remain flexible enough to minimize stress concentrations in the solar panels. The support members may be attached to a solar panel by a support member attachment module incorporated into an automated solar panel production line. A plurality of solar panels may be field mounted to a solar panel support structure having one or more piles or the like with at least a lower and upper transverse support rails spanning the plurality of solar panels. Each solar panel may be further retained by clearance fit end brackets as well. The solar panels discussed herein may vary in size, and may have a light receiving surface having an area as large as 2.2 meters×2.6 meters.

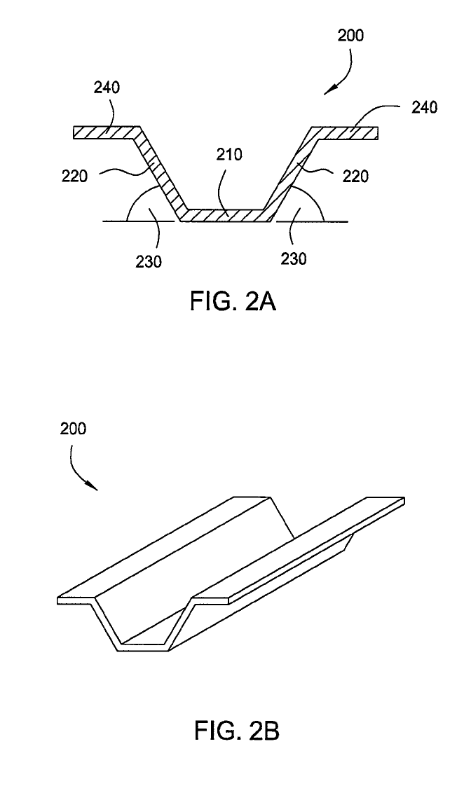

FIG. 2A illustrates a cross-sectional view and FIG. 2B illustrates an isometric view according to one embodiment of an elongated member 200 for mounting a solar panel. The elongated member 200 may include a lower, structural mounting surface 210 for engagement with a transverse support rail or some other supporting member attached to a mounting structure, such as one or more structural piles or the like, for mounting one or more solar panels. Flexible support portions 220 extend upwardly and outwardly from structural mounting surface 210 in a V-shaped manner. In other words, each flexible support portion 220 should form an angle 230 with the structural mounting surface 210 of between about 10 degrees and about 80 degrees. Angle 230 may be between about 20 degrees and about 70 degrees. Angle 230 may be between about 30 degrees and about 60 degrees, such as about 45 degrees. Panel mounting portions 240 extend outwardly from each flexible support portion 220 and are configured to engage the backside of a planar solar panel.

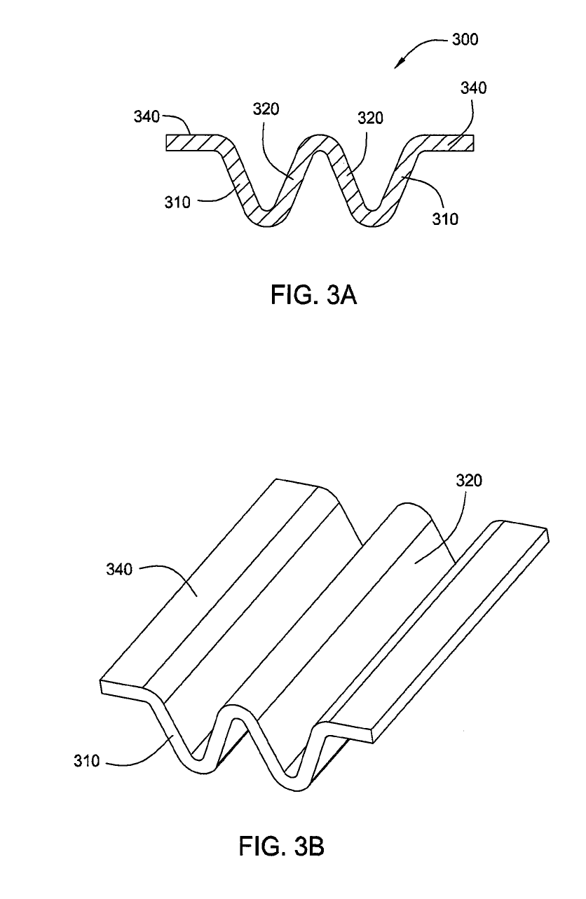

FIG. 3A illustrates a cross-sectional view and FIG. 3B illustrates an isometric view according to another embodiment of an elongated member 300 for mounting a solar panel. The elongated member 300 may have a generally W-shaped cross-section with substantially vertical outer sections 310 and inner sections 320 extending upwardly and inwardly from the lower ends of the outer sections 310. Panel mounting portions 340 extend outwardly from the upper end of each outer section 310 and are configured to engage the backside of a planar solar panel. The cross-sections of the elongated members illustrated in FIGS. 2A and 3A are not intended to be limiting of the scope of the invention discussed herein, since one skilled in the art would appreciate that the shape, cross-sectional area, and materials used to form the elongated members can be adjusted to provide a desired structural stiffness, provide a desired amount of support to the solar cell, reduce the mechanical stress induced in the solar cell from external sources (e.g., wind, thermal expansion), and/or achieve a desired cost target.

The elongated member 200, 300 may comprise a formed steel sheet, such as 16, 18, or 20 gauge cold-rolled steel. Other materials having similar strength and flexibility may be used as well. Additionally, the elongated member 200, 300 may be coated with a suitable coating for corrosion resistance. For instance, elongated member 200, 300 may comprise an aluminum-zinc coating, such as a coating containing 55% aluminum and 45% zinc by weight. The nominal coating thickness may be between about 15 μm and about 30 μm on each side of elongated member 200, 300. In one embodiment, the elongated member 200, 300 is constructed of galvanized steel. Alternatively, the elongated member 200, 300 may be constructed of a plastic or cardboard material if to be used solely as a shipping spacer.

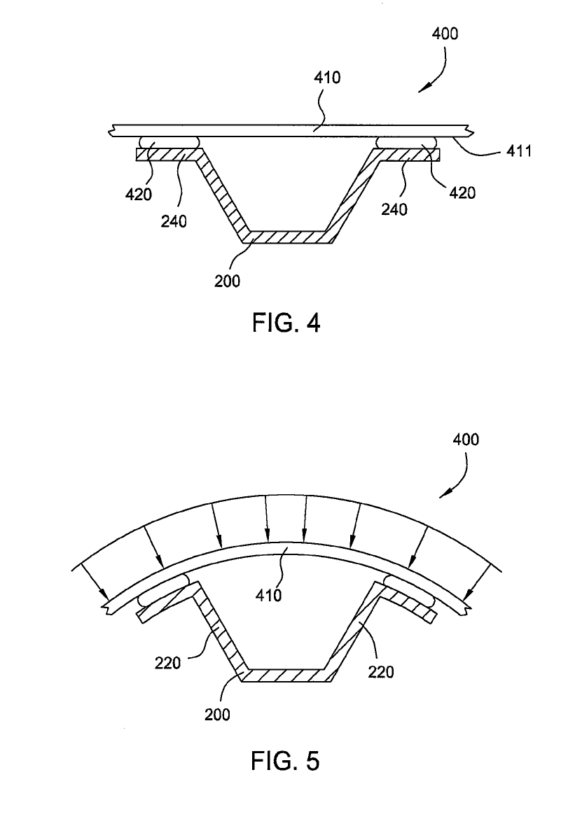

FIG. 4 is a partial schematic cross-sectional view of one embodiment of a solar panel mounting configuration 400 of the present invention. The configuration 400 comprises a solar panel 410 attached to the panel mounting portions 240 of the elongated member 200 via adhesive members 420. The adhesive members 420 should be strong enough to withstand tensile loading from any wind uploading condition of about 2,400 Pa or more, yet the adhesive members should remain flexible enough to allow movement of elongated member 200 during extreme loading conditions of the solar panel 410 due to wind, ice, or snow loading. In one embodiment, the adhesive members 420 are bonded to a non-light receiving surface 411 of the solar panel 410.

Adhesive members 420 may comprise a structural glazing tape suitable for bonding glass materials to metallic structures. The structural glazing tape may comprise conformable, acrylic closed cell foam having a high performance acrylic adhesive applied to both sides. Examples of structural glazing tapes, which may be used in embodiments of the present invention, include VHB Structural Glazing Tapes manufactured by 3M in St. Paul, Minn.

One embodiment of the present invention may include an adhesion promoter in conjunction with structural glazing tape. Glass materials, such as those used in solar panels, are hydrophilic. This characteristic makes an adhesive bond, particularly with an acrylic adhesive, susceptible to degradation under high humidity or when otherwise exposed to high moisture environments. In order to prevent this problem, the solar panel may be surface treated with an adhesion promoter, such as a silane coupling agent, to reduce the hydrophilic nature of the solar panel 410 and enhance the adhesive bond between the solar panel 410 and the adhesive member 420. One such adhesion promoter that may be used in the present invention is 3-glycidoxypropyl trimethoxysilane resin. An example of this adhesion promoter is Z-6040 Silane manufactured by Dow Corning Corporation in Midland, Mich.

Alternatively, the adhesive member may comprise adhesive glue suitable for bonding glass to metal structures and having the aforementioned characteristics of the structural glazing tape.

FIG. 5 is a partial schematic cross-sectional view of the embodiment of the solar panel mounting configuration in FIG. 4 under exaggerated loading conditions. As shown in FIG. 5, as the solar panel 410 is placed under loading from wind, ice, or snow, a bending moment is created about the elongated member 200 as the solar panel 410 deflects to each side. The elongated member 200 of the present invention absorbs this loading by deflection of the flexible support portions 220. This flexibility allows the stress in the solar panel 410 to be spread across a wider area, preventing high stress concentrations in the glass about the elongated member 200. Thus, breakage is reduced as compared with prior art solar panel mounting and support devices.

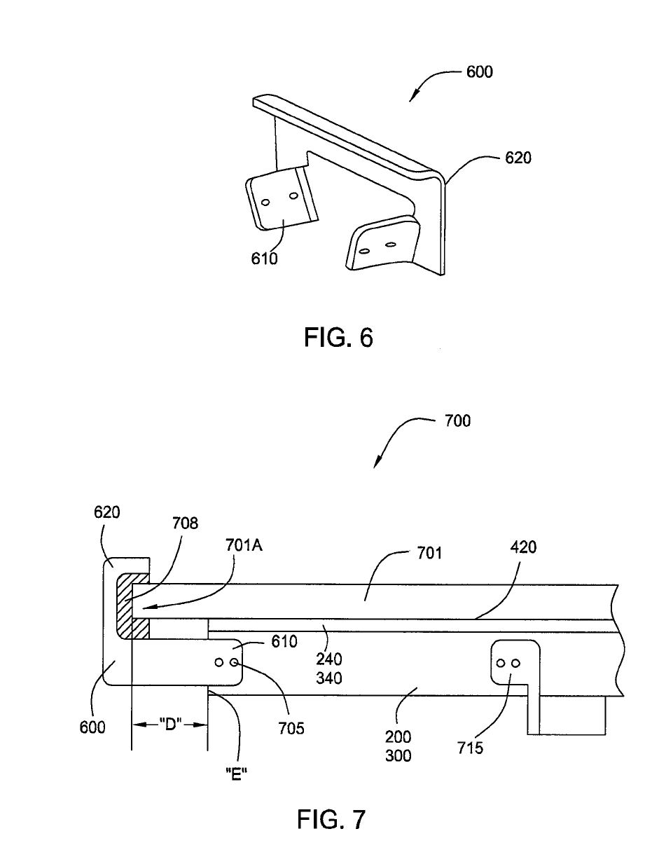

In one embodiment, a solar panel may be further retained by one or more end brackets to prevent slippage of the laminated glass members due to slow plastic creeping of the lamination material (e.g., PVB or EVA). FIG. 6 is an isometric view of one embodiment of an end bracket 600 according to the present invention. The end bracket 600 includes mounting flaps 610, which may be attached to an elongated member 200 via a fastening means such as adhesive, screws, or rivets. The end bracket 600 further includes a curved panel retaining portion 620. In use, the panel retaining portion 620 may include a compliant member 708, such as rubber or other elastomeric material, to reduce the potential for abrasion and/or stress cracking of the solar cell's edges due to the application of external loads, such as wind loading, or thermal expansion.

FIG. 7 is a partial cross-section view of one illustrative embodiment of a solar panel mounting configuration 700 in accordance with the present invention. The configuration 700 comprises a solar panel 701 attached to the panel mounting portions 240, 340 of the elongated member 200, 300 via the adhesive member 420. The configuration further comprises the end bracket 600 attached to the elongated member 200, 300 at mounting flaps 610 via fasteners 705. In this embodiment, the elongated member 200, 300 does not fully extend to the edge of the solar panel 701. The distance “D” between the edge 701A of the solar panel 701 and the corresponding edge “E” of the elongated member 200, 300 may be between about 50 mm and about 300 mm. The panel retaining portion 620 of the end bracket 600 extends outwardly and around the edge 701A of the solar panel 701. This configuration reduces stress concentrations at the edge portion of the solar panel 701, which reduces the potential for creating cracks and chips in one of the components of the solar cell, such as a glass containing substrate element. Since solar panels typically have surfaces near their edges that have been mechanically ground or abraded, which can create areas where cracks can initiate during normal environmental loading, it is believed that by configuring the elongated member 200, 300 to only receive a portion of a surface of the solar panel 701 that is not near these affected regions, the chances of stress induced crack migration will be reduced, and thus improve the average useable lifetime of the solar panel.

Referring to FIG. 7, in one embodiment, a compliant member 708 may be positioned between the end bracket 600 and the edge 701A of the solar panel 701 to further reduce stress concentrations and abrasive wear created between the end bracket 600 and the edge of the solar panel 701. The solar panel mounting configuration 700 may further include a support bracket 715 for mounting the elongated member 200, 300 to a transverse support rail (not shown) or other structural cross-members that are adapted to receive one or more of the elongated member 200, 300 of one or more mounted solar cells.

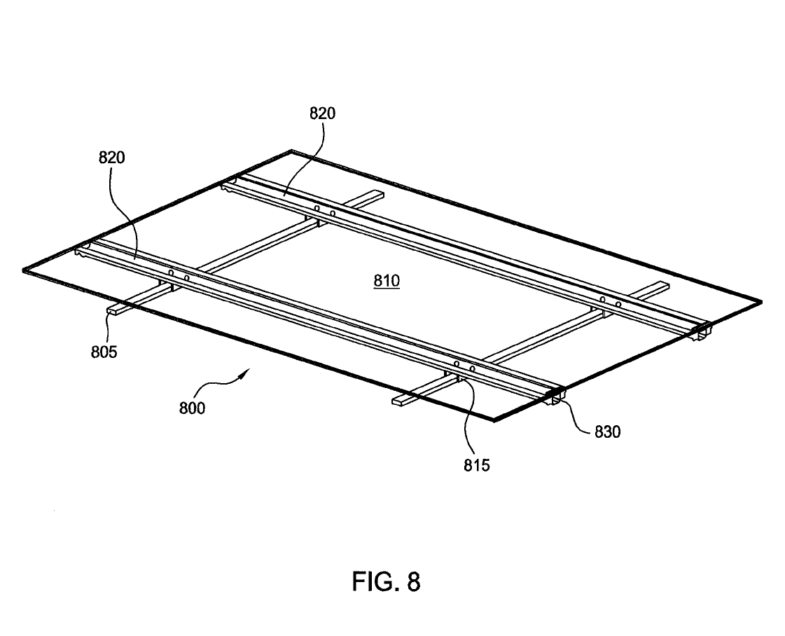

FIG. 8 is an isometric view of one illustrative embodiment of a solar panel mounting configuration 800 in accordance with the present invention. In this embodiment, elongated members 820 are attached to transverse support rails 805 via support brackets 815. A solar panel 810 is attached to the elongated members 820 along the length of the non-light receiving surface of the solar panel 810 as previously set forth. The solar panel 810 may be further retained at the edges of the solar panel 810 via end brackets 830. In this embodiment two elongated members 820 are shown spanning the length of the solar panel 810. However, other embodiments may include any number of elongated members 820 spanning the length of the solar panel 810.

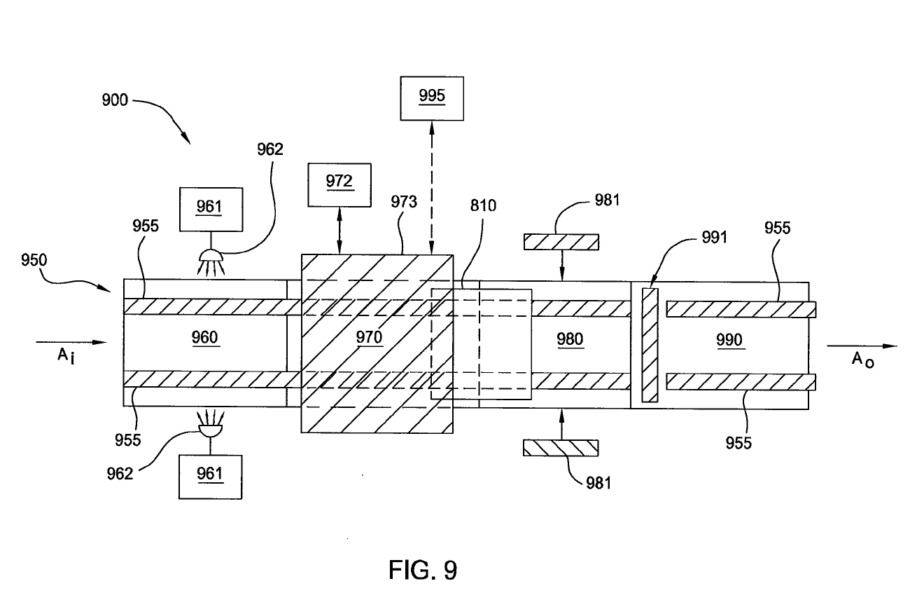

FIG. 9 is a plan view of a support member attachment module 900 that can be used to bond the elongated support members 820 to a surface of the solar panel 810 in an automated or semi automated fashion. The support member attachment module 900 includes a cleaning module 960, a drying region 970, a support member placement region 980, and a support member attachment region 990 that are all connected by way of an automation system 950. In general, the support member attachment module 900 is positioned to receive the solar panel 810 from an automation device that is connected to a solar panel testing module, perform a support member attachment process, and deliver the solar panel 810 to an unload module following paths Aᵢ and A₀ within a back end of an automated solar panel production line.

The automation system 950 is generally a conveying system that is used to support and transfer the solar panel 810 through the various sections of the support member attachment module 900. In one example, as shown in FIG. 9, the automation system 950 comprises a series of actuated conveyor belts 955 that are controlled by commands sent from a system controller 995.

In the first step of attaching elongated support members 820 to the solar panel 810 via the support member attachment module 900, the cleaning module 960 is adapted to perform one or more cleaning and preparation processes to the non-light receiving surface of the solar panel 810 so that the elongated support members 820 can be securely and reliably attached in a subsequent step. The cleaning and preparation process may include a cleaning fluid rinse of the non-light receiving surface of the solar panel 810, gas purge of the surface to remove particles, and/or the application of a primer or other material (e.g., glue) to the surface that can be used to help promote or form a bond between the non-light receiving surface of the solar panel 810 and the elongated support members 820. In one embodiment, a cleaning fluid or primer material is delivered from one or more source vessels 961 through a nozzle 962 to the non-light receiving surface of the solar panel 810.

In the next step, the solar panel 810 is transferred to the drying region 970 where the solar panel 810 is dried to remove any contaminants that might affect the bonding process. In one embodiment, the drying region 970 includes a hood 973 and an exhaust device 972 (e.g., fan) that are adapted to dry the surface of the solar panel 810 by promoting evaporation of the cleaning solution components and/or collect vapors emanating from the primer or other chemicals delivered during the cleaning process.

In the next step, the solar panel 810 is transferred to the support member placement region 980 where the elongated support members 820 are placed on the solar panel 810 by use of robotic devices 981. The robotic devices 981 may be conventional robotic devices that are positioned to receive an elongated support member 820 from a receiving area (not shown) and place the elongated support member 820 on a desired region of the solar panel 810. In one embodiment, prior to placement of the elongated support member 820 on the solar panel 810 an amount of a glue or tape material, such as the adhesive member 420, is affixed to a bonding surface of the elongated support member 820 that is placed against the non-light receiving surface of the solar panel 810 by the robotic device 981.

In the next step, the solar panel 810 is transferred through the support member attachment region 990 where the elongated support member 820 is urged against the non-light receiving surface of the solar panel 810, which is supported on the automation system 950, by use of one or more automated rollers 991. In one embodiment, the automated roller 991 is generally weighted to provide a desired load to the elongated support member 820 and the solar panel 810 to assure that the elements used to bond the elongated support member 820 to the solar panel 810 are in contact. In another embodiment, the force applied by the automated roller 991 by an actuator (not shown) and the speed with which the solar panel 810 is fed through the automated rollers 991 by the automation system 950 components is controlled by the system controller 995. Next, solar panel 810 can be transferred to an unload module using one or more of the automation system 950 components.

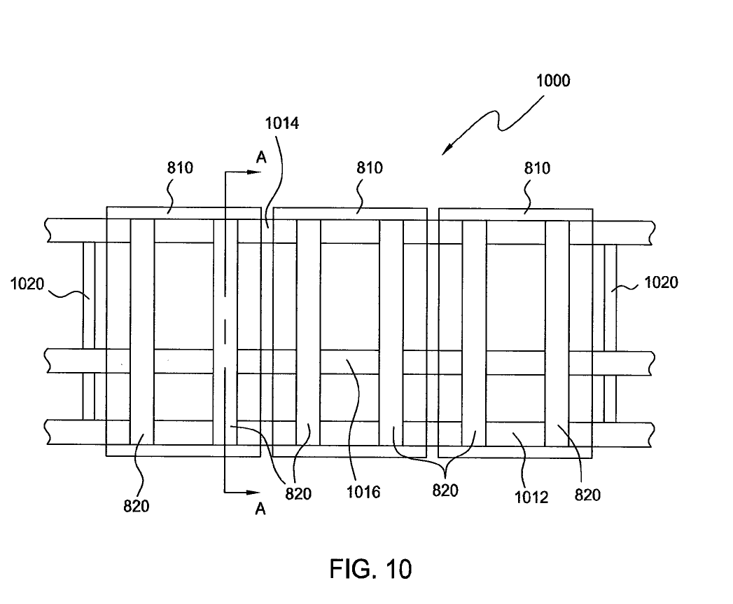

FIG. 10 is a schematic plan view of a solar panel field mounting configuration 1000 according to one embodiment of the present invention. The solar panel field mounting configuration may include one or more solar panels 810 (depicted as transparent for clarity) mounted to one or more solar panel support structures 1010. In one embodiment, the solar panel support structure 1010 comprise a lower transverse rail 1012 and an upper transverse rail 1014 attached to a lower support structure 1020, which may be a galvanized steel pile or other support structure typical for supporting solar panels in field or rooftop configurations. In one embodiment, the solar panel support structure 1010 also includes one or more middle transverse rails 1016 disposed between the lower transverse rail 1012 and the upper transverse rail 1014 and attached to the lower support structure 1020.

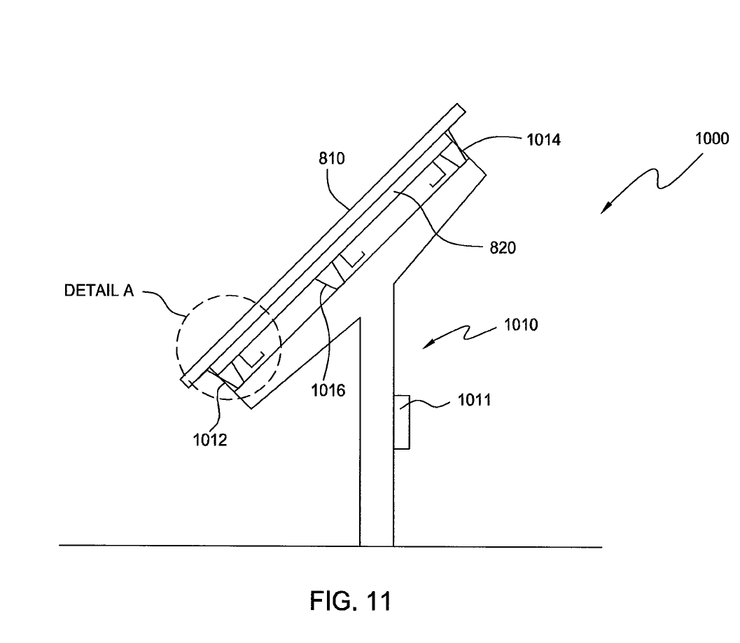

FIG. 11 is a schematic cross-sectional view of the mounting configuration 1000 as viewed along section A-A of FIG. 10. As seen in FIG. 11, each solar panel 810, already having the elongated members 820 attached, is placed onto the solar panel support structure 1010 and attached thereto. In one embodiment, the elongated members 820 may be disposed into mating slot regions formed in the lower transverse rail 1012, the upper transverse rail 1014, and the one or more middle transverse rails 1016, respectively. In one embodiment, the lower support structure 1010 includes a region 1011 for attaching monitoring or other electrical devices.

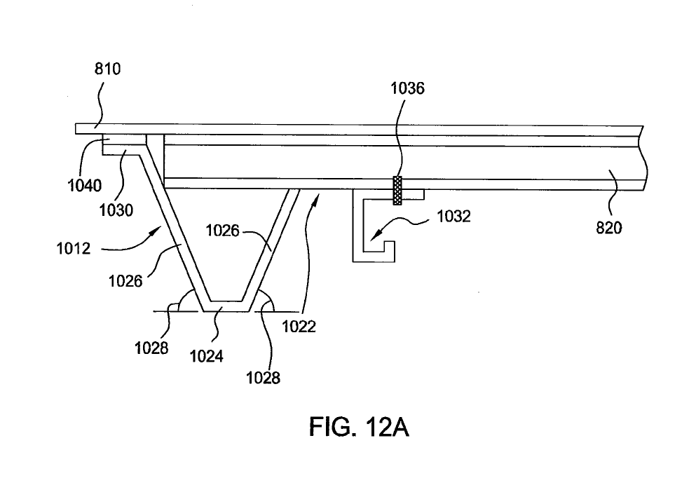

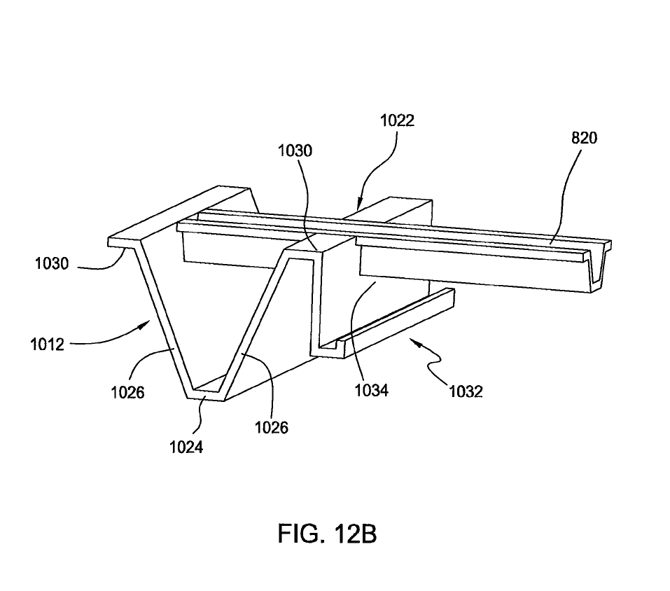

FIG. 12A is a schematic enlarged view of the region of FIG. 11 labeled “Detail A.” FIG. 12B is a schematic isometric view of the region depicted in FIG. 12A with the solar panel 810 removed for clarity.

Referring to FIGS. 11, 12A, and 12B, each elongated member 820 attached to each solar panel 810 may be placed into a mating slot region 1022 in each lower transverse support rail 1012. As shown in FIGS. 12A and 12B, the lower transverse support rail 1012 may include a lower surface 1024 having flexible support portions 1026 extending upwardly and outwardly from the lower surface 1024 in a generally V-shaped manner forming an angle 1028 with the lower surface 1024 of between about 10 degrees and about 80 degrees. The angle 1028 may be between about 20 degrees and about 70 degrees. In one embodiment, the angle 1028 is between about 30 degrees and about 60 degrees, such as about 45 degrees. Panel mounting portions 1030 may extend outwardly from each flexible support portion 1026 and may be configured to engage the backside of the solar panel 810. In one embodiment, the lower transverse support rail 1012 includes a tray member 1032 extending from one or both of the panel mounting portions 1030, which may be useful for supporting cables used in electrical connections with the solar panel 820.

As shown in FIGS. 11, 12A, and 12B, each of the elongated members 820 may engage the slot region 1022 formed in at least a portion of the lower transverse support rail 1012. In one embodiment, the slot region 1022 only extends through the panel mounting portion 1030 and the flexible support portion 1026 located on the inboard side of the solar panel mounting configuration 1000. In one embodiment, the slot region 1022 also extends through a portion of the tray member 1032 as well. Thus, the panel mounting portion 1030 and the flexible support portion 1026 situated on the outboard side of the panel mounting configuration 1000 may provide lower support to the elongated members 820 for ease of installation.

In one embodiment, the lower transverse support rail 1012 includes a plurality of mounting tabs 1034, which may have some compliance for supporting each elongated member 820. In one embodiment, a fastener 1036 is used to attach the elongated member 820 to the lower transverse rail 1012 and provide an electrical connection for grounding purposes. The fastener 1036 may be a metallic screw, rivet, or other conductive fastening device. In one embodiment, the lower transverse rail 1012 is electrically attached to the lower support 1010, which is electrically grounded.

Referring to FIG. 12A, the each solar panel 810 may be attached to each panel mounting portion 1030 of the lower transverse rail 1012 via an adhesive member 1040. In one embodiment, the adhesive member 1040 is similar to the adhesive member 420 previously described.

In one embodiment of the present invention, the upper transverse rail 1014 is a mirror image of the lower transverse rail 1012. As such, the upper transverse rail 1014 may also include a slot region 1022 receiving each elongated member 820 as well. Additionally, the solar panel 810 may also be attached to the upper transverse rail 1014 via the adhesive member 1040 and panel mounting portions 1030. In one embodiment, the upper transverse rail 1014 also includes a mounting tab 1034 for attaching to each elongated member 820 with the fastener 1036.

In one embodiment, the one or more middle transverse rails 1016 are identical to the lower transverse rail 1012 and the upper transverse rail 1014 except the slot region 1022 of the middle transverse rails 1016 extends through both panel mounting portions 1030 and both flexible support portions 1026. As such each solar panel 810 may also be attached to the panel mounting portions 1030 of each middle transverse rail 1016 via the adhesive member 1040. In one embodiment, each middle transverse rail 1016 also includes a mounting tab 1034 for attaching to each elongated member 820 with the fastener 1036.

In one embodiment, the lower transverse rail 1012, the upper transverse rail 1014, and the one or more middle transverse rails 1016 may comprise a formed steel sheet, such as appropriate gauge cold-rolled steel. Other materials having similar strength and flexibility may be used as well. In one embodiment, the rails may be coated for corrosion resistance. In one embodiment, an aluminum/zinc coating, such as a coating containing 55% aluminum and 45% zinc by weight may be used. Nominal coating thickness may be between about 15 μm and about 30 μm. In one embodiment, the lower transverse rail 1012, the upper transverse rail 1014, and the one or more middle transverse rails 1016 comprise galvanized steel.

The cross-sections of the lower transverse rail 1012, the upper transverse rail 1014, and the one or more middle transverse rails 1016 illustrated in FIGS. 12A and 12B are illustrative and not intended to be limiting to the scope of the invention discussed herein, since one skilled in the art would appreciate that the shape, cross-sectional area, and materials used to form them can be adjusted to provide a desired structural stiffness, provide a desired amount of support to the solar panel, reduce the mechanical stress induced in the solar panel from external sources (e.g., wind and thermal expansion), and/or achieve a desired cost target.

While the foregoing is directed to embodiments of the present invention, other and further embodiments of the invention may be devised without departing from the basic scope thereof, and the scope thereof is determined by the claims that follow.

1. A solar panel assembly, comprising:
a solar panel having a non-light receiving surface;
a substantially V-shaped support member having a corrosion resistant coating; and
a moisture resistant adhesive bonding member attaching the substantially V-shaped support member to the non-light receiving surface of the solar panel, wherein the substantially V-shaped member substantially spans a length of the solar panel.

2. The solar panel assembly of claim 1, wherein the substantially V-shaped support member comprises:
a horizontal base portion;
a first and second flexible portions extending upwardly and outwardly from the horizontal base portion;
a first horizontal panel mounting portion extending outwardly from the first flexible portion; and
a second horizontal panel mounting portion extending outwardly from the second flexible portion.

3. The solar panel of claim 2, wherein the corrosion resistant coating comprises aluminum and zinc.

4. The solar panel assembly of claim 2, further comprising an adhesion promoter.

5. The solar panel assembly of claim 4, wherein the adhesion promoter is a silane coupling agent and the adhesive bonding member is an acrylic-based double sided tape.

6. A solar panel support attachment module, comprising:
a system controller configured to send and receive commands;
a solar panel cleaning region configured receive commands from the system controller and clean a non-light receiving surface of the solar panel;
a solar panel drying module configured to receive commands from the system controller and dry the non-light receiving surface of the solar panel;
a support member placement module configured to receive commands from the system controller and position a support member on the non-light receiving surface of the solar panel;
a support member attachment module configured to receive commands from the system controller and attach the support member to the non-light receiving surface of the solar panel; and
an automation system configured to receive commands from the system controller and move the solar panel through the solar panel support attachment module.

7. The solar panel support attachment module of claim 6, wherein the support placement module comprises a robotic device configured to receive the support member and position the support member on the non-light receiving surface of the solar panel.

8. The solar panel support attachment module of claim 7, wherein the support placement module is further configured to affix an adhesive member to the support member.

9. The solar panel support attachment module of claim 8, wherein the support member attachment module comprises an automated roller configured to provide a load to the support member as the solar panel is moved through the support member attachment module.

10. The solar panel support attachment module of claim 9, wherein the cleaning module comprises a cleaning fluid nozzle configured to spray the cleaning fluid onto the non-light receiving surface of the solar panel and a cleaning fluid vessel configured to supply a cleaning fluid to the cleaning fluid nozzle.

11. The solar panel support attachment module of claim 10, wherein the drying module comprises a hood and an exhaust device configured to dry the non-light receiving surface of the solar panel.

12. A method for attaching a support member to a solar panel, comprising:
receiving the solar panel onto an automation device;
positioning the solar panel within a cleaning module via the automation device;
cleaning a non-light receiving surface of the solar panel;
transferring the solar panel into a drying module via the automation device;
drying the non-light receiving surface of the solar panel;
transferring the solar panel into a support member placement module via the automation device;
positioning a support member onto the non-light receiving surface of the solar panel;
transferring the solar panel into a support member attachment module via the automation device; and
attaching the support member to the non-light receiving surface of the solar panel.

13. The method of claim 12, wherein positioning the support member comprises robotically receiving and positioning the support member via a robotic device controlled by a system controller.

14. The method of claim 13, further comprising affixing an adhesive member to the support member prior to positioning the support member onto the non-light receiving surface of the solar panel.

15. The method of claim 14, wherein attaching the support member comprises urging the support member against the solar panel via a support panel roller as the solar panel moved via the automation device.

16. The method of claim 15, wherein cleaning the solar panel comprises spraying the non-light receiving surface of the solar panel with a cleaning fluid via a cleaning fluid nozzle.

17. The method of claim 16, wherein drying the solar panel comprises drying the non-light receiving surface of the solar panel via a hood and an exhaust device.

18. A solar panel support assembly, comprising:
a lower support structure;
a lower transverse support rail attached to the lower support structure, wherein the lower transverse support rail has a plurality of slots disposed therein each configured to receive a solar panel support member affixed to the solar panel;
an upper transverse support rail attached to the lower support structure, wherein the upper transverse support rail has a plurality of slots disposed therein each configured to receive the solar panel support member affixed to the solar panel; and
an adhesive member affixed to the lower transverse support rail and the upper transverse support rail and configured to adhere to a non-light receiving surface of the solar panel.

19. The assembly of claim 18, wherein the upper transverse rail and the lower transverse rail each comprise a substantially V-shaped support section and a cable loading region.

20. The assembly of claim 19, further comprising a middle transverse support rail attached to the lower support structure, wherein the middle transverse support rail has a plurality of slots disposed therein each configured to receive the solar panel support member affixed to the solar panel, wherein the middle transverse support rail comprises a substantially V-shaped support section and a cable loading region.

21. The assembly of claim 19, wherein at least one of the lower transverse support rail and the upper transverse support rail comprises a tab and a fastener configured to electrically connect the solar panel support member to the solar panel support assembly.

22. A method for mounting a solar panel, comprising:
affixing an adhesive member to an upper mounting surface of a lower transverse rail and an upper mounting surface of an upper transverse rail of a grounded lower support member;
positioning the solar panel onto the adhesive member of the lower transverse rail and the upper transverse rail; and
attaching the solar panel to the upper mounting surface of the lower transverse rail and the upper mounting surface of the upper transverse rail.

23. The method of claim 22, further comprising positioning a metallic support member attached to the solar panel into slots disposed through the lower transverse support rail and the upper transverse support rail.

24. The method of claim 23, further comprising electrically connecting the metallic support member to at least one of the lower transverse support rail and the upper transverse support rail.
